(19) United States
(12) Patent Application Publication
(10) Pub. No.: US 2025/0301580 A1
(43) Pub. Date: Sep. 25, 2025

(54) DISPLAY DEVICE

(71) Applicant: Samsung Display Co., Ltd., Yongin-si (KR)

(72) Inventors: GYEONGHO JEONG, Yongin-si (KR); SOJEONG LA, Yongin-si (KR); JAIKU SHIN, Yongin-si (KR); Jihye SHIN, Yongin-si (KR); SUNG CHUL CHOI, Yongin-si (KR)

(21) Appl. No.: 18/984,192

(22) Filed: Dec. 17, 2024

(30) Foreign Application Priority Data
Mar. 22, 2024 (KR) 10-2024-0039720

(51) Int. Cl. H05K 5/02; H10K 59/80

(52) U.S. Cl. CPC H05K 5/02; H10K 59/80

(57) ABSTRACT

A display device includes: a display module; a first support plate below the display module, and including a first non-folding part and a folding part along a first direction; a first flat plate below the first non-folding part; a first wing plate below the folding part, and adjacent to the first flat plate in the first direction; and a first sub-wing plate between the folding part and the first wing plate. The first wing plate has a width greater than that of the first sub-wing plate in the first direction.

### CROSS-REFERENCE TO RELATED APPLICATION

The present application claims priority to and the benefit of Korean Patent Application No. 10-2024-0039720, filed on Mar. 22, 2024, in the Korean Intellectual Property Office, the entire disclosure of which is incorporated by reference herein.

### BACKGROUND

### 1. Field

Aspects of embodiments of the present disclosure relate to a display device.

### 2. Description of the Related Art

Electronic equipment for providing an image to a user, such as smartphones, digital cameras, laptop computers, navigation systems, and smart televisions, include a display device for displaying an image. The display device generates an image to provide the image to the user through a display screen.

In recent years, various kinds of display devices have been developed with the development of technology of the display devices. For example, various flexible display devices that may be deformed into a curved shape, folded, or rolled are being developed. Flexible display devices of which the shapes thereof are capable of being variously modified may be more easily carried, and may improve a user's convenience.

Among the flexible display devices, a foldable display device includes a display module that is foldable based on a folding axis extending in one direction. The display module may be folded or unfolded about the folding axis. The display module includes a folding area that is bent during a folding operation. The folding area may be curved to have a predetermined radius of curvature.

The above information disclosed in this Background section is for enhancement of understanding of the background of the present disclosure, and therefore, it may contain information that does not constitute prior art.

### SUMMARY

One or more embodiments of the present disclosure may be directed to a display device that is capable of preventing or substantially preventing adhesive layers, through which wing plates may be adhered to a first support plate, from being visible.

According to one or more embodiments of the present disclosure, a display device includes: a display module; a first support plate below the display module, and including a first non-folding part and a folding part along a first direction; a first flat plate below the first non-folding part; a first wing plate below the folding part, and adjacent to the first flat plate in the first direction; and a first sub-wing plate between the folding part and the first wing plate. The first wing plate has a width greater than that of the first sub-wing plate in the first direction.

In an embodiment, the display device may further include a first-1 adhesive layer between the folding part and the first sub-wing plate.

In an embodiment, the first-1 adhesive layer and the first sub-wing plate may have the same thickness as each other in a direction perpendicular to a plane of the display module.

In an embodiment, the first-1 adhesive layer may have a width less than that of the first sub-wing plate in the first direction.

In an embodiment, the display device may further include a second-1 adhesive layer between the first wing plate and the first sub-wing plate.

In an embodiment, the second-1 adhesive layer may have a thickness greater than that of the first-1 adhesive layer in a direction perpendicular to a plane of the display module.

In an embodiment, the second-1 adhesive layer may have a width less than that of the first-1 adhesive layer in the first direction, and may be located adjacent to one side of the first wing plate that does not face the first flat plate.

In an embodiment, the second-1 adhesive layer may have a thickness greater than that of the first sub-wing plate in a direction perpendicular to a plane of the display module.

In an embodiment, the display device may further include: a second-1 support plate between the first non-folding part and the first flat plate; and a third-1 adhesive layer between the second-1 support plate and the first flat plate.

In an embodiment, the third-1 adhesive layer may have a thickness greater than that of the second-1 adhesive layer in a direction perpendicular to a plane of the display module.

In an embodiment, the first support plate may further include a second non-folding part along the first direction together with the first non-folding part and the folding part. The folding part may be located between the first non-folding part and the second non-folding part. The folding part may include: a curved portion having a plurality of openings defined therein; a first extension portion between the curved portion and the first non-folding part; a second extension portion between the curved portion and the second non-folding part; a first inverse curvature portion between the first extension portion and the first non-folding part; and a second inverse curvature portion between the second extension portion and the second non-folding part. When the folding part is folded, the curved portion may be bent to have a curvature. The first and second inverse curvature portions may be configured to be bent in a direction opposite to that of the curved portion.

In an embodiment, the display device may further include: a second flat plate below the second non-folding part; a second wing plate below the folding part, adjacent to the second flat plate in the first direction, and located together with the first wing plate along the first direction; and a second sub-wing plate between the folding part and the second wing plate. The second wing plate may have a width greater than that of the second sub-wing plate in the first direction.

In an embodiment, when the folding part is unfolded, the first wing plate and the first sub-wing plate may overlap with the first extension portion, and the second wing plate and the second sub-wing plate may overlap with the second extension portion. The first and second wing plates and the first and second sub wing-plates may not overlap with the curved portion.

In an embodiment, the display device may further include: a first-2 adhesive layer between the folding part and the second sub-wing plate; a second-2 adhesive layer between the second wing plate and the second sub-wing plate; a second-2 support plate between the second non-folding part and the second flat plate; and a third-2 adhesive layer between the second-2 support plate and the second flat plate.

In an embodiment, in a direction perpendicular to a plane of the display module, the first-2 adhesive layer and the second sub-wing plate may have the same thickness as each other, and the second-2 adhesive layer may have a thickness greater than that of the first-2 adhesive layer. The first-2 adhesive layer may have a width less than that of the second sub-wing plate in the first direction.

In an embodiment, the second-2 adhesive layer may have a width less than that of the first-2 adhesive layer in the first direction, and the second-2 adhesive layer may be adjacent to one side of the second wing plate that faces the first wing plate.

In an embodiment, in a direction perpendicular to a plane of the display module, the second-2 adhesive layer may have a thickness greater than that of the second sub-wing plate, and the third-2 adhesive layer may have a thickness greater than that of the second-2 adhesive layer.

According to one or more embodiments of the present disclosure, a display device includes: a display module; a first support plate below the display module, and including a first non-folding part, a folding part, and a second non-folding part along a first direction; a first flat plate below the first non-folding part; a second flat plate below the second non-folding part; a first wing plate below the folding part, and adjacent to the first flat plate; a second wing plate below the folding part, and adjacent to the second flat plate; a first sub-wing plate between the folding part and the first wing plate; and a second sub-wing plate between the folding part and the second wing plate. In the first direction, the first wing plate has a width greater than that of the first sub-wing plate, and the second wing plate has a width greater than that of the second sub-wing plate.

In an embodiment, the display device may further include: a second-1 support plate between the first non-folding part and the first flat plate; a second-2 support plate between the second non-folding part and the second flat plate; a first-1 adhesive layer between the folding part and the first sub-wing plate; and a first-2 adhesive layer between the folding part and the second sub-wing plate. In the first direction, the first and second sub-wing plates may be located between the second-1 support plate and the second-2 support plate.

According to one or more embodiments of the present disclosure, a display device includes: a display module; a first support plate below the display module, and including non-folding parts along a first direction, and a folding part between the non-folding parts; a first wing plate below the folding part; a second wing plate below the folding part, and located together with the first wing plate along the first direction; a first sub-wing plate between the folding part and the first wing plate; and a second sub-wing plate between the folding part and the second wing plate. Each of the first and second wing plates has a width greater than that of each of the first and second sub-wing plates in the first direction.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view of a display device according to an embodiment of the present disclosure;

FIG. 2 is a view illustrating a folded state of the display device of FIG. 1;

FIG. 3 is a plan view of a display panel used in the display device of FIG. 1;

FIG. 4 is a cross-sectional view illustrating an example of the display panel of FIG. 3;

FIG. 5 is a more detailed cross-sectional view of the display panel corresponding to one pixel in FIG. 4;

FIG. 6 is a cross-sectional view of the display device taken along the line I-I′ of FIG. 3;

FIG. 7 is a cross-sectional view taken along the line II-II′ of FIG. 3;

FIG. 8 is an enlarged view illustrating a second non-folding part and the elements below the second non-folding part in FIG. 6;

FIG. 9 is a perspective view of a support plate of FIG. 6;

FIG. 10 is an enlarged plan view illustrating the area AA of FIG. 9;

FIG. 11 is a cross-sectional view taken along the line III-III′ of FIG. 3 in a state in which a bending area is bent;

FIG. 12 is a view illustrating a folded state of the display device of FIG. 6; and

FIG. 13 is a view of a case in which a display module and a support part are to be accommodated therein according to an embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

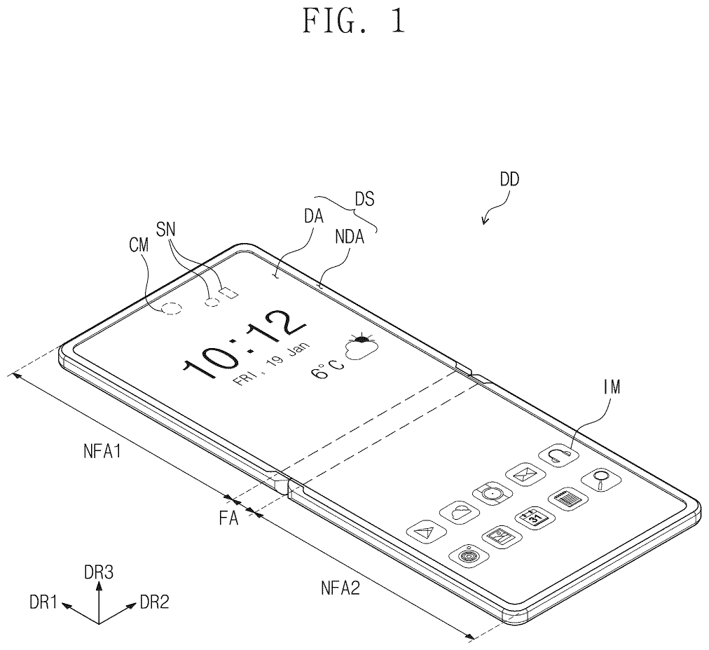

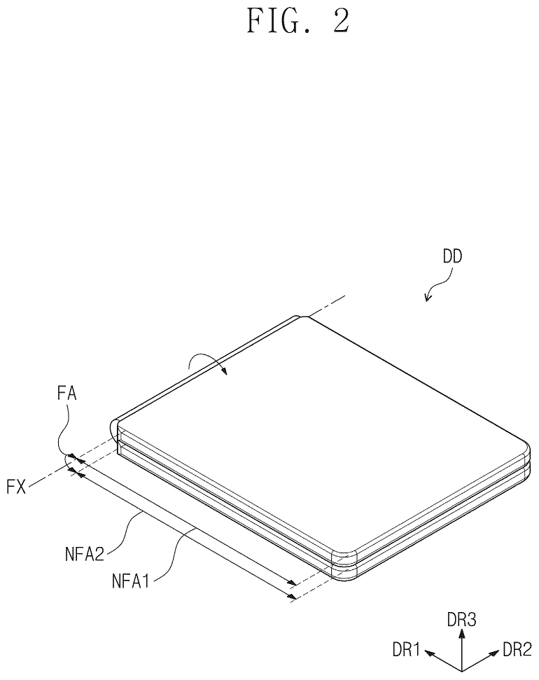

FIG. 1 is a perspective view of a display device according to an embodiment of the present disclosure. FIG. 2 is a view illustrating a folded state of the display device of FIG. 1.

Referring to FIG. 1, a display device DD according to an embodiment of the present disclosure has a rectangular shape having long sides extending in a first direction DR1, and short sides extending in a second direction DR2 crossing the first direction DR1. However, the present disclosure is not limited thereto. For example, the display device DD may have various suitable shapes, such as a circular shape, a polygonal shape, or the like. The display device DD may be a flexible display device.

Hereinafter, a direction that perpendicularly or substantially perpendicularly crosses a plane defined by the first direction DR1 and the second direction DR2 is defined as a third direction DR3. As used herein, the phrases “viewed from the plane” and “in a plan view” may be defined as a state in which an object portions is viewed in the third direction DR3. In addition, as used herein, the term “overlapping” and the like may mean a state in which the components are arranged to overlap with each other when viewed on a plane (e.g., in a plan view).

The display device DD may include a folding area FA, and a plurality of non-folding areas NFA1 and NFA2. The non-folding areas NFA1 and NFA2 may include a first non-folding area NFA1 and a second non-folding area NFA2. The folding area FA may be disposed between the first non-folding area NFA1 and the second non-folding area NFA2. The first non-folding area NFA1, the folding area FA, and the second non-folding area NFA2 may be arranged along the first direction DR1.

As an example, one folding area FA and two non-folding areas NFA1 and NFA2 are illustrated, but the present disclosure is not limited thereto. In other words, the number of folding areas FA and the number of non-folding areas NFA1 and NFA2 may be variously modified as needed or desired. For example, the display device DD may include more than two non-folding areas, and a plurality of folding areas between the non-folding areas.

A top surface of the display device DD may be defined as a display surface DS, and may have a plane defined by the first direction DR1 and the second direction DR2. Images IM generated from the display device DD may be provided to a user through the display surface DS.

The display surface DS may include a display area DA, and a non-display area NDA around the display area DA. An image may be displayed on the display area DA, but may not be displayed on the non-display area NDA. The non-display area NDA may surround (e.g., around a periphery of) the display area DA, and may define an edge of the display device DD, which is printed with a suitable color (e.g., a predetermined color).

The display device DD may include a plurality of sensors SN, and at least one camera CM. The sensors SN and the camera CM may be adjacent to an edge of the display device DD. The sensors SN and the camera CM may be disposed on the display area DA adjacent to the non-display area NDA. The sensors SN and the camera CM may be disposed on the first non-folding area NFA1, but the arranged positions of the sensors SN and the camera CM are not limited thereto.

For example, the sensors SN may be a proximity sensor, but the kind of the sensors SN are not limited thereto. The camera CM may photograph an external image.

Referring to FIG. 2, the display device DD may be a folding-kind (e.g., a foldable) display device DD that is capable of being folded or unfolded. For example, the folding area FA may be bent with respect to a folding axis FX that is parallel to or substantially parallel to the second direction DR2, and thus, the display device DD may be folded.

When folding the display device DD, the first non-folding area NFA1 and the second non-folding areas NFA2 may face each other, and the display device DD may be in-folded to prevent the display surface DS from being exposed to the outside. However, the present disclosure is not limited thereto. For example, the display device DD may be out-folded so that the display surface DS is exposed to the outside with respect to the folding axis FX.

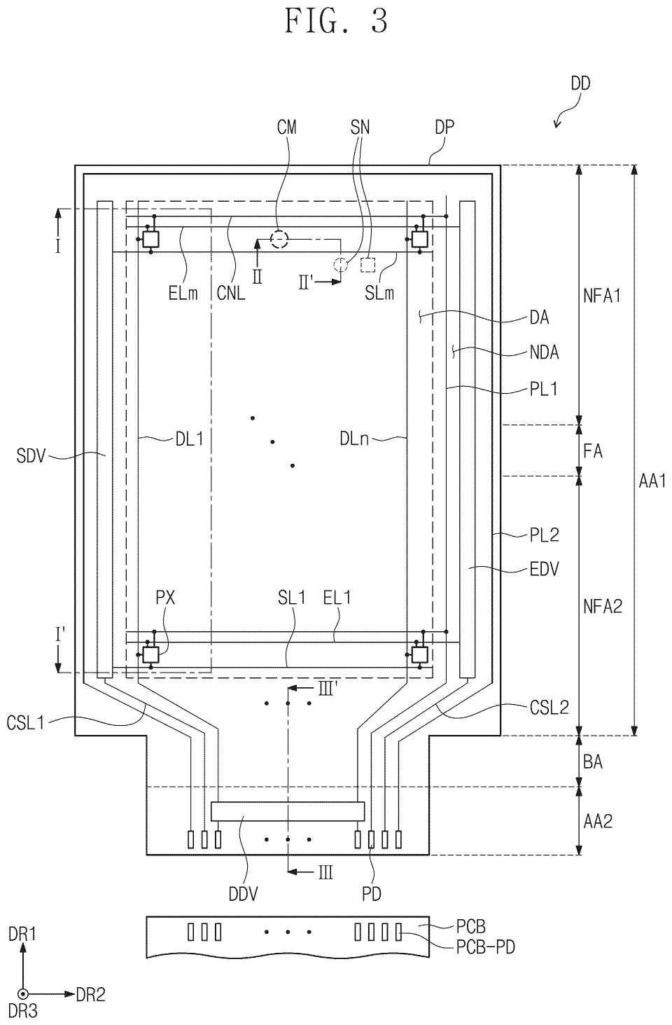

FIG. 3 is a plan view of a display panel used in the display device of FIG. 1.

Referring to FIG. 3, the display device DD may include a display panel DP, a scan driver SDV, a data driver DDV, and an emission driver EDV.

According to an embodiment of the present disclosure, the display panel 110 may be an emission-kind of display panel. For example, the display panel DP may be an organic light emitting display panel or an inorganic light emitting display panel. An emission layer of the organic light emitting display panel may include an organic light emitting material. An emission layer of the inorganic light emitting display panel may include a quantum dot, a quantum rod, and/or the like. Hereinafter, for convenience of illustration, the display panel DP may be described in more detail in the context of an organic light emitting display panel.

The display panel DP may be a flexible display panel. For example, the display panel DP may include a plurality of electronic elements that are disposed on a flexible substrate. The display panel DP may extend to be longer in the first direction DR1 than in the second direction DR2. The display panel DP may have a plane defined by the first and second directions DR1 and DR2.

The display panel DP may include a first area AA1, a second area AA2, and a bending area BA disposed between the first area AA1 and the second area AA2. The bending area BA extends in the second direction DR2, and the first area AA1, the bending area BA, and the second area AA2 may be arranged along the first direction DR1.

The first area AA1 may have long sides that extend in the first direction DR1, and are opposite to each other in the second direction DR2. A length of each of the bending area BA and the second area AA2 in the second direction DR2 may be less than that of the first area AA1.

The first area AA1 may include a display area DA, and a non-display area NDA around the display area DA. The non-display area NDA may surround (e.g., around a periphery of) the display area DA. An image may be displayed on the display area DA, but may not be displayed on the non-display area NDA. The second area AA2 and the bending area BA may be areas on which an image is not displayed. The sensors SN and the cameras CM may be disposed on the display area DA.

When viewed in the second direction DR2, the first area AA1 may include a first non-folding area NFA1, a second non-folding area NFA2, and a folding area FA disposed between the first non-folding area NFA1 and the second non-folding area NFA2.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a first power line PL1, a second power line PL2, a plurality of connection lines CNL, and a plurality of pads PD, where m and n are natural numbers. The pixels PX may be disposed on the display area DA, and may be connected to the scan lines SL1 to SLm, the data lines DL1 to DLn, and the emission lines EL1 to ELm.

The scan driver SDV and the emission driver EDV may be disposed on the non-display area NDA. The scan driver SDV and the emission driver EDV may be disposed on the non-display area NDA that is adjacent to each of the long sides of the first area AA1. The data driver DDV may be disposed on the second area AA2. The data driver DDV may be manufactured in the form of an integrated circuit chip, and may be mounted on the second area AA2.

The scan lines SL1 to SLm may extend in the second direction DR2, and may be connected to the scan driver SDV. The data lines DL1 to DLn may extend in the first direction DR1, and may be connected to the data driver DDV via the bending area BA. The emission lines EL1 to ELm may extend in the second direction DR2, and may be connected to the emission driver EDV.

The first power line PL1 may extend in the first direction DR1, and may be disposed on the non-display area NDA. The first power line PL1 may be disposed between the display area DA and the emission driver EDV. However, the present disclosure is not limited thereto, and the first power line PL1 may be disposed between the display area DA and the scan driver SDV.

The first power line PL1 may extend to the second area AA2 via the bending area BA. The first power line PL1 may extend toward a lower end of the second area AA2 when viewed on a plane (e.g., in a plan view). The first power line PL1 may receive a first voltage.

The second power line PL2 may be disposed on the non-display area NDA adjacent to the long sides of the first area AA1, and the non-display area NDA facing the second area AA2 with the display area DA therebetween. The second power line PL2 may be disposed outside the scan driver SDV and the light emission driver EDV.

The second power line PL2 may extend to the second area AA2 via the bending area BA. The second power line PL2 may extend from the second area AA2 in the first direction DR1 with the data driver DDV therebetween. The second power line PL2 may extend toward a lower end of the second area AA2 when viewed on a plane.

The second power line PL2 may receive a second voltage having a level less than that of the first voltage. The second power line PL2 may extend to the display area DA and be connected to the pixels PX, and the second voltage may be provided to the pixels PX through the second power line PL2.

The connection lines CNL may extend in the second direction DR2, and may be arranged along the first direction DR1. The connection lines CNL may be connected to the first power line PL1 and the pixels PX. The first voltage may be applied to the pixels PX through the first power line PL1 and the connection lines CNL, which are connected to each other.

The first control line CSL1 may be connected to the scan driver SDV, and may extend toward the lower end of the second area AA2 via the bending area BA. The second control line CSL2 may be connected to the emission driver EDV, and may extend toward the lower end of the second area AA2 via the bending area BA. The data driver DDV may be disposed between the first control line CSL1 and the second control line CSL2.

When viewed on the plane, the pads PD may be disposed adjacent to the lower end of the second area AA2. The data driver DDV, the first power line PL1, the second power line PL2, the first control line CSL1, and the second control line CSL2 may be connected to the pads PD.

The data lines DL1 to DLn may be connected to corresponding pads PD through the data driver DDV. For example, the data lines DL1 to DLn may be connected to the data driver DDV, and the data drivers DDV may be connected to the pads PD, which respectively correspond to the data lines DL1 to DLn.

The display device DD may include a printed circuit board PCB connected to the pads PD. The connection pads PCB-PD may be disposed on the printed circuit board PCB, and the connection pads PCB-PD may be connected to the pads PD.

A timing controller may be disposed on the printed circuit board PCB. The timing controller may be connected to the pads PD through the printed circuit board. The timing controller may control the operations of the scan driver SDV, the data driver DDV, and the emission driver EDV. The timing controller may generate a scan control signal, a data control signal, and an emission control signal in response to control signals received from the outside.

The scan control signal may be provided to the scan driver SDV through the first control line CSL1. The emission control signal may be provided to the emission driver EDV through the second control line CSL2. The data control signal may be provided to the data driver DDV. The timing controller may receive image signals from the outside, and convert a data format of the image signals to match an interface specification with the data driver DDV, and thus, may provide the converted data format to the data driver DDV.

The scan driver SDV may generate a plurality of scan signals in response to the scan control signals. The scan signals may be applied to the pixels PX through the scan lines SL1 to SLm. The scan signals may be sequentially applied to the pixels PX.

The data driver DDV may generate a plurality of data voltages corresponding to image signals in response to the data control signals. The data voltages may be provided to the pixels PX through the data lines DL1 to DLn. The emission driver EDV may generate a plurality of emission signals in response to the emission control signals. The emission signals may be applied to the pixels PX through the emission lines EL1 to ELm.

The pixels PX may receive the data voltages in response to the scan signals. The pixels PX may emit light having a luminance corresponding the data voltages in response to the emission signals to display an image. An emission time of the pixels PX may be controlled by the emission signals.

A voltage generation part (e.g., a voltage generator) may be disposed on the printed circuit board PCB. The voltage generation part may be connected to the pads PD through the printed circuit board PCB. The voltage generation part may generate the first voltage and the second voltage. The first voltage and the second voltage may be applied to the first power line PL1 and the second power line PL2, respectively.

Each of the pixels PX may include an organic light emitting element. The first voltage may be applied to an anode of the organic light emitting element, and the second voltage may be applied to a cathode of the organic light emitting element. The organic light emitting element may operate by receiving the first voltage and the second voltage.

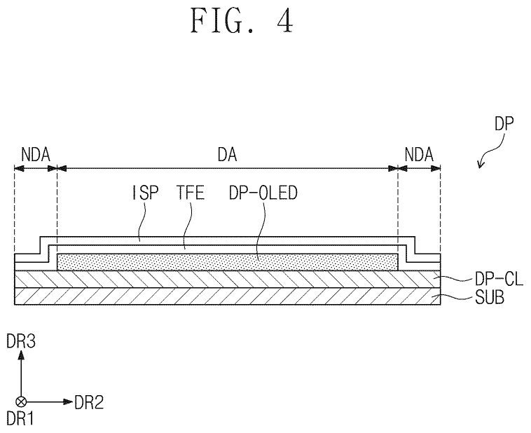

FIG. 4 is a cross-sectional view illustrating an example of the display panel of FIG. 3.

For example, FIG. 4 illustrates a cross-section of the display panel DP when viewed in the first direction DR1.

Referring to FIG. 4, the display panel DP may include a substrate SUB, a circuit element layer DP-CL disposed on the substrate SUB, a display element layer DP-OLED disposed on the circuit element layer DP-CL, a thin film encapsulation layer TFE disposed on the display element layer DP-OLED, and an input sensing part ISP disposed on the thin film encapsulation layer TFE. The display element layer DP-OLED may be disposed on the display area DA.

The substrate SUB may include the display area DA, and the non-display area NDA around the display area DA. The substrate SUB may include a flexible plastic material. For example, the substrate SUB may include polyimide (PI).

The circuit element layer DP-CL may include transistors. The display element layer DP-OLED may include light emitting elements connected to the transistors. The pixels PX illustrated in FIG. 3 may include the transistors and the light emitting elements.

The thin film encapsulation layer TFE may be disposed on the circuit element layer DP-CL to cover the display element layer DP-OLED. The thin film encapsulation layer TFE may include an inorganic layer, an organic layer, and an inorganic layer, which are sequentially laminated. Each of the inorganic layers may include an inorganic material, and may protect the pixels PX against moisture/oxygen. The organic layer may include an organic material, and may protect the pixels PX against foreign materials, such as dust particles.

The input sensing part ISP may include a plurality of sensors that senses an external input. The sensors may sense the external input in a capacitive manner. The external input may include various suitable kinds of inputs, such as a portion of the user's body, a pen, light, heat, or a pressure.

The input sensing part ISP may be directly manufactured on the thin film encapsulation layer TFE when the display panel DP is manufactured. However, the present disclosure is not limited thereto, and the input sensing part ISP may be provided as a panel that is separated from the display panel DP, and may be attached to the display panel DP by an adhesive layer.

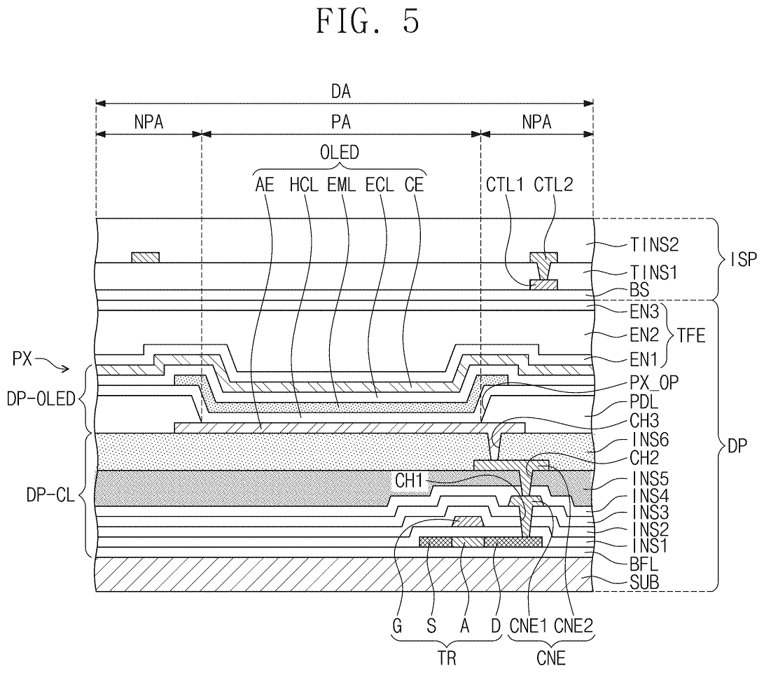

FIG. 5 is a more detailed cross-sectional view of the display panel corresponding to one pixel in FIG. 4.

Referring to FIG. 5, the display panel DP includes the pixel PX, and the pixel PX may include a transistor TR and a light emitting element OLED. The light emitting element OLED may include a first electrode AE (e.g., an anode), a second electrode CE (e.g., a cathode), a hole control layer HCL, an electron control layer ECL, and an emission layer EML.

The transistor TR and the light emitting element OLED may be disposed on the substrate SUB. For example, one transistor TR is illustrated, but substantially, the pixel PX may include a plurality of transistors and at least one capacitor to drive the light emitting element OLED.

The display area DA may include an emission area PA corresponding to each of the pixels PX, and a non-emission area NPA around the emission area PA. The light emitting element OLED may be disposed on the emission area PA.

A buffer layer BFL may be disposed on the substrate SUB, and the buffer layer BFL may be an inorganic layer. A semiconductor pattern may be disposed on the buffer layer BFL. The semiconductor pattern may include polysilicon, amorphous silicon, or a metal oxide.

The semiconductor pattern may be doped with an N-type dopant or a P-type dopant. The semiconductor pattern may include a highly doped region and a lowly doped region. The highly doped region may have a conductivity greater than that of the lowly doped region to substantially serve as a source electrode and a drain electrode of the transistor TR. The lowly doped region may substantially correspond to an active (e.g., a channel) of the transistor.

A source S, an active A, and a drain D of the transistor TR may be formed from the semiconductor pattern. A first insulating layer INS1 may be disposed on the semiconductor pattern. The gate G of the transistor TR may be disposed on the first insulating layer INS1. A second insulating layer INS2 may be disposed on the gate G. A third insulating layer INS3 may be disposed on the second insulating layer INS2.

The connection electrode CNE may include a first connection electrode CNE1 and a second connection electrode CNE2 to connect the transistor TR to the light emitting element OLED. The first connection electrode CNE1 may be disposed on the third insulating layer INS3, and may be connected to the drain D through a first contact hole CH1 defined in the first to third insulating layers INS1 to INS3.

A fourth insulating layer INS4 may be disposed on the first connection electrode CNE1. A fifth insulating layer INS5 may be disposed on the fourth insulating layer INS4. The second connection electrode CNE2 may be disposed on the fifth insulating layer INS5. The second connection electrode CNE2 may be connected to the first connection electrode CNE1 through a second contact hole CH2 defined in the fourth and fifth insulating layers INS4 and INS5.

A sixth insulating layer INS6 may be disposed on the second connection electrode CNE2. A layer provided from the buffer layer BFL to the sixth insulating layer INS6 may be defined as the circuit element layer DP-CL. Each of the first insulating layer INS1 to the sixth insulating layer INS6 may be an inorganic layer or an organic layer.

The first electrode AE may be disposed on the sixth insulating layer INS6. The first electrode AE may be connected to the second connection electrode CNE2 through a third contact hole CH3 defined in the sixth insulating layer INS6. A pixel defining layer PDL, in which an opening for exposing a portion (e.g., a predetermined portion) of the first electrode AE is defined, may be disposed on the first electrode AE and the sixth insulating layer INS6.

The hole control layer HCL may be disposed on the first electrode AE and the pixel defining layer PDL. The hole control layer HCL may include a hole transport layer and a hole injection layer.

The emission layer EML may be disposed on the hole control layer HCL. The emission layer EML may be disposed on an area corresponding to the opening PX_OP. The emission layer EML may include an organic material and/or an inorganic material. The emission layer EML may emit one of a red light, a green light, or a blue light.

The electronic control layer ECL may be disposed on the hole control layer HCL to cover the emission layer EML. The electron control layer ECL may include an electron transport layer and an electron injection layer. The hole control layer HCL and the electron control layer ECL may be commonly disposed on the emission area PA and the non-emission area NPA.

The second electrode CE may be disposed on the electronic control layer ECL. The second electrode CE may be commonly disposed in the pixels PX. The layer at (e.g., in or on) which the light emitting element OLED is disposed may be defined as the display element layer DP-OLED.

The thin film encapsulation layer TFE may be disposed on the second electrode CE to cover the pixel PX. The thin film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2.

Each of the first and third encapsulation layers EN1 and EN3 may include an inorganic insulating layer, and may protect the pixel PX against moisture/oxygen. The second encapsulation layer EN2 may include an organic insulating layer, and may protect the pixel PX against foreign substances, such as dust particles.

A first voltage may be applied to the first electrode AE through the transistor TR, and a second voltage having a level lower than that of the first voltage may be applied to the second electrode CE. Holes and electrons injected into the light emitting layer EML may be coupled to each other to form excitons. While the excitons transition to a ground state, the light emitting element OLED may emit light.

The layers from the substrate SUB to the thin film encapsulation layer TFE may be defined as the display panel DP. The input sensing part ISP may be disposed on the thin film encapsulation layer TFE. The input sensing part ISP may be manufactured directly on a top surface of the thin film encapsulation layer TFE.

A base layer BS may be disposed on the thin film encapsulation layer TFE. The base layer BS may include an inorganic insulating layer. At least one inorganic insulating layer may be provided on the thin film encapsulation layer TFE as the base layer BS.

The input sensing part ISP may include a first conductive pattern CTL1, and a second conductive pattern CTL2 disposed on the first conductive pattern CTL1. The first conductive pattern CTL1 may be disposed on the base layer BS. A first insulating layer TINS1 may be disposed on the base layer BS to cover the first conductive pattern CTL1. The first insulating layer TINS1 may include an inorganic insulating layer or an organic insulating layer.

The second conductive pattern CTL2 may be disposed on the first insulating layer TINS1. The second insulating layer TINS2 may be disposed on the first insulating layer TINS1 to cover the second conductive pattern CTL2. The second insulating layer TINS2 may include an organic insulating layer.

The first and second conductive patterns CTL1 and CTL2 may overlap with the non-emission area NPA. The first and second conductive patterns CTL1 and CTL2 may be disposed on the non-emission area NPA between the emission areas PA, and may have a mesh shape.

The first and second conductive patterns CTL1 and CTL2 may form sensors of the above-described input sensing part ISP. For example, the mesh-shaped first and second conductive patterns CTL1 and CTL2 may be spaced apart (e.g., separated) from each other in a region (e.g., a predetermined region) to form the sensors. A portion of the second conductive pattern CTL2 may be connected to the first conductive pattern CTL1.

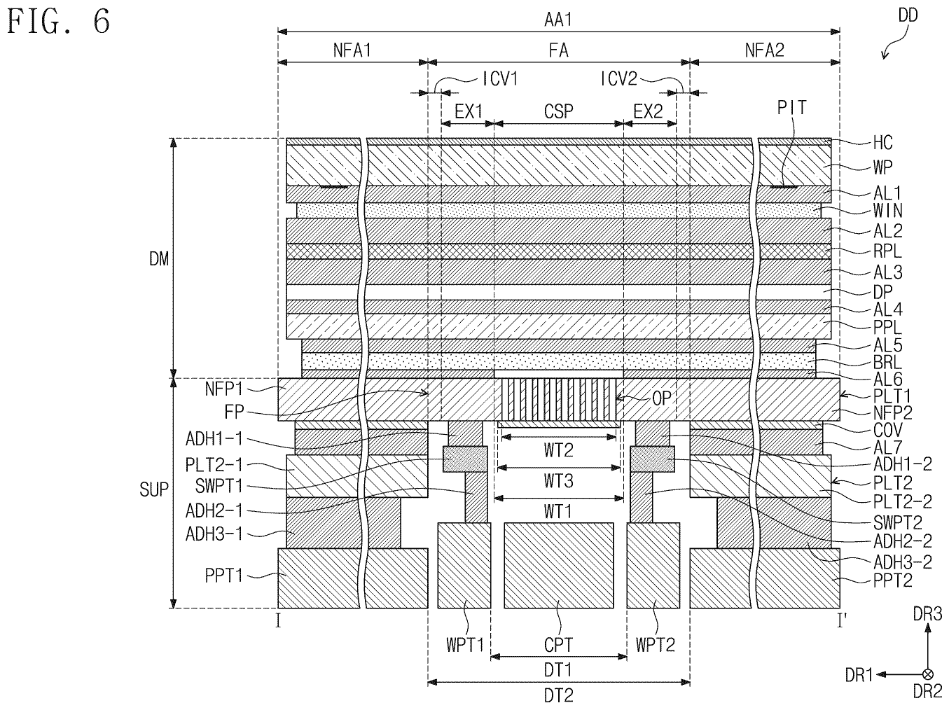

FIG. 6 is a cross-sectional view of the display device taken along the line I-I′ of FIG. 3.

Referring to FIG. 6, a display device DD according to an embodiment of the present disclosure may include a display module (e.g., a display layer) DM, and a support part SUP disposed below the display module DM. The display module DM may be a flexible display module. The display module DM may include a first non-folding area NFA1, a folding area FA, and a second non-folding area NFA2, which are arranged along the first direction DR1, in the same manner as that of the display panel DP. The support part SUP may be disposed below (e.g., underneath) the display module DM to support the display module DM.

Hereinafter, more detailed configurations of the display module DM and the support part SUP will be described based on a flat state of the display device DD.

The display module DM may include a display panel DP, an anti-reflection layer RPL, a window WIN, a window protective layer WP, a hard coating layer HC, a panel protective layer PPL, a barrier layer BRL, and first to sixth adhesive layers AL1 to AL6. The anti-reflection layer RPL, the window WIN, the window protective layer WP, and the hard coating layer HC may be disposed on the display panel DP. The panel protective layer PPL may be disposed below (e.g., underneath) the display panel DP.

The anti-reflection layer RPL may be disposed on the display panel DP. The anti-reflection layer RPL may be defined as an external light anti-reflection film. The anti-reflection layer RPL may reduce a reflectance of the external light incident to the display panel DP from the outside.

When the external light traveling toward the display panel DP is reflected from the display panel DP and provided again to an external user, the user may visually recognize the external light, like a mirror. To prevent or substantially prevent this phenomenon from occurring, for example, the anti-reflection layer RPL may include a plurality of color filters that display the same colors as those of the pixels.

The color filters may filter external light to display the same colors as those of the pixels. In this case, the external light may not be visually recognized by the user. However, the present disclosure is not limited thereto, and the anti-reflection layer RPL may include a phase retarder and/or a polarizer to reduce a reflectance of the external light.

The window WIN may be disposed on the anti-reflection layer RPL. The window WIN may protect the display panel DP and the anti-reflection layer RPL from external scratches. The window WIN may have optically transparent properties. The window WIN may include glass. However, the present disclosure is not limited thereto, and the window WIN may include a synthetic resin film.

The window WIN may have a single layer structure or a multilayered structure. For example, the window WIN may include a plurality of plastic films that are bonded to each other by using an adhesive, or may include a glass substrate and a plastic film, which are bonded to each other by using an adhesive.

The window protective layer WP may be disposed on the window WIN. The window protective layer WP may include a flexible plastic material, such as polyimide or polyethylene terephthalate. The hard coating layer HC may be disposed on a top surface of the window protective layer WP.

A printing layer PIT may be disposed on a bottom surface of the window protective layer WP. The printing layer PIT may have a black color, but the color of the printing layer PIT is not limited thereto. The printing layer PIT may be adjacent to an edge of the window protective layer WP.

The first adhesive layer AL1 may be disposed between the window protective layer WP and the window WIN. The window protective layer WP and the window WIN may be bonded to each other by the first adhesive layer AL1. The first adhesive layer AL1 may cover the printing layer PIT below (e.g., underneath) a bottom surface of the window protective layer WP.

The second adhesive layer AL2 may be disposed between the window WIN and the anti-reflection layer RPL. The window WIN and the anti-reflection layer RPL may be bonded to each other by the second adhesive layer AL2.

The third adhesive layer AL3 may be disposed between the anti-reflection layer RPL and the display panel DP. The anti-reflection layer RPL and the display panel DP may be bonded to each other by the third adhesive layer AL3.

The panel protective layer PPL may be disposed below (e.g., underneath)

the display panel DP. The panel protective layer PPL may protect a lower portion of the display panel DP. The panel protective layer PPL may include a flexible plastic material. For example, the panel protective layer PPL may include polyethylene terephthalate (PET).

The barrier layer BRL may be disposed below the panel protective layer PPL. A resistance to a compression force due to external pressing may be increased by the barrier layer BRL. Accordingly, the barrier layer BRL may serve to prevent or substantially prevent a deformation of the display panel DP from occurring. The barrier layer BRL may include a flexible plastic material, such as polyimide or polyethylene terephthalate.

The barrier layer BRL may have a color that absorbs light. The barrier layer BRL may have a black color. In this case, when viewing the display module DM from an upper side of the display module DM, the components disposed below the barrier layer BRL may not be visually recognized.

A fourth adhesive layer AL4 may be disposed between the display panel DP and the panel protective layer PPL. The display panel DP and the panel protective layer PPL may be bonded to each other by the fourth adhesive layer AL4.

The fifth adhesive layer AL5 may be disposed between the panel protective layer PPL and the barrier layer BRL. The panel protective layer PPL and the barrier layer BRL may be bonded to each other by the fifth adhesive layer AL5.

A sixth adhesive layer AL6 may be disposed below the barrier layer BRL. The sixth adhesive layer AL6 may be disposed between the barrier layer BRL and a first support plate PLT1 of the support part SUP. The barrier layer BRL and the first support plate PLT1 may be bonded to each other by the sixth adhesive layer AL6.

Each of the first to sixth adhesive layers AL1 to AL6 may include a transparent adhesive, such as a pressure sensitive adhesive (PSA) or an optically clear adhesive (OCA), but the kind of adhesive is not limited thereto.

As used herein, the “thickness” may be defined as a value measured in the third direction DR3. The third direction DR3 may be defined as a direction perpendicular to or substantially perpendicular to a plane of the display module DM (e.g., a top or bottom surface of the display module DM in the flat state). As used herein, the “width” may be defined as a value measured in a horizontal direction (e.g., the first direction DR1 or the second direction DR2).

A thickness of the panel protective layer PPL may be less than that of the window protective layer WP. A thickness of the anti-reflection layer RPL may be less than that of the panel protective layer PPL. A thickness of the display panel DP may be less than that of the anti-reflection layer RPL. The thickness of the window WIN may be the same or substantially the same as the thickness of the anti-reflection layer RPL. The thickness of the barrier layer BRL may be less than that of the panel protective layer PPL, and may be greater than that of the anti-reflection layer RPL.

For example, the thickness of the window protective layer WP may be about 75 micrometers (μm), and the thickness of the panel protective layer PPL may be about 50 micrometers (μm). The thickness of each of the anti-reflection layer RPL and the window (WIN) may be about 31 micrometers (μm). The thickness of the display panel DP may be about 30 micrometers (μm), and the thickness of the barrier layer BRL may be about 35 micrometers (μm).

A thickness of the first adhesive layer AL1 may be the same or substantially the same as that of the barrier layer BRL. A thickness of each of the second adhesive layer AL2 and the third adhesive layer AL3 may be the same or substantially the same as that of the panel protective layer PPL. A thickness of each of the fourth and fifth adhesive layers AL4 and AL5 may be less than that of the display panel DP. The fourth adhesive layer AL4 and the fifth adhesive layer AL5 may have the same or substantially the same thickness as each other. A thickness of the sixth adhesive layer AL6 may be less than that of each of the fourth and fifth adhesive layers AL4 and AL5. A thickness of the hard coating layer HC may be less than that of the sixth adhesive layer AL6.

For example, the first adhesive layer AL1 may have a thickness of about 35 micrometers (μm), and each of the second adhesive layer AL2 and the third adhesive layer AL3 may have a thickness of about 50 micrometers (μm). The thickness of each of the fourth adhesive layer AL4 and the fifth adhesive layer AL5 may be about 25 micrometers (μm). The thickness of the sixth adhesive layer AL6 may be about 16 micrometers (μm), and the thickness of the hard coating layer HC may be about 5 micrometers (μm).

The display panel DP, the anti-reflection layer RPL, the panel protective layer PPL, and the second to fourth adhesive layers AL2 to AL4 may have the same or substantially the same width as each other. The window protective layer WP, the hard coating layer HC, and the first adhesive layer AL1 may have the same or substantially the same width as each other.

A width of the window WIN may be less than that of each of the display panel DP, the anti-reflection layer RPL, the panel protective layer PPL, and the second to fourth adhesive layers AL2 to AL4. In addition, the width of the window WIN may be less than that of each of the window protective layer WP, the hard coating layer HC, and the first adhesive layer AL1.

When viewed on a plane, an edge of the window WIN may be disposed inside edges of the display panel DP, the anti-reflection layer RPL, the panel protective layer PPL, and the second to fourth adhesive layers AL2 to AL4. In addition, when viewed on the plane, the edge of the window WIN may be disposed inside the edges of the window protective layer WP, the hard coating layer HC, and the first adhesive layer AL1.

When viewed on the plane, the barrier layer BRL and the fifth and sixth adhesive layers AL5 and AL6 may have the same or substantially the same width as each other. When viewed on the plane, edges of the barrier layer BRL and the fifth and sixth adhesive layers AL5 and AL6 may be disposed inside the edge of the window WIN.

The support part SUP may include the first support plate PLT1, a cover layer COV, a second support plate PLT2, flat plates PPT1 and PPT2, wing plates WPT1 and WPT2, sub-wing plates SWPT1 and SWPT2, a center plate CPT, a seventh adhesive layer AL7, first-1 and first-2 adhesive layers ADH1-1 and ADH1-2, second-1 and second-2 adhesive layers ADH2-1 and ADH2-2, and third-1 and third-2 adhesive layers ADH3-1 and ADH3-2.

The first support plate PLT1 may be disposed below (e.g., underneath) the display module DM to support the display module DM. The first support plate PLT1 may have a rigidity greater than that of the display module DM. Openings OP overlapping with the folding area FA may be defined in the first support plate PLT1.

The first support plate PLT1 may include a metal material, such as stainless steel. For example, the first support plate PLT1 may include SUS 304, but the present disclosure is not limited thereto. For example, the first support plate PLT1 may include various suitable metal materials. However, the present disclosure is not limited thereto, and the first support plate PLT1 may include a non-metal material, such as glass or plastic.

The first support plate PLT1 may include a first non-folding part NFP1, a folding part FP, and a second non-folding part NFP2. For example, boundaries between the first non-folding part NFP1, the folding part FP, and the second non-folding part NFP2 are shown as dotted lines on the first support plate PLT1 in FIG. 6.

The first non-folding part NFP1, the folding part FP, and the second non-folding part NFP2 may be arranged along the first direction. The folding part FP may be disposed between the first non-folding part NFP1 and the second non-folding part NFP2. The openings OP may be defined in the folding part FP.

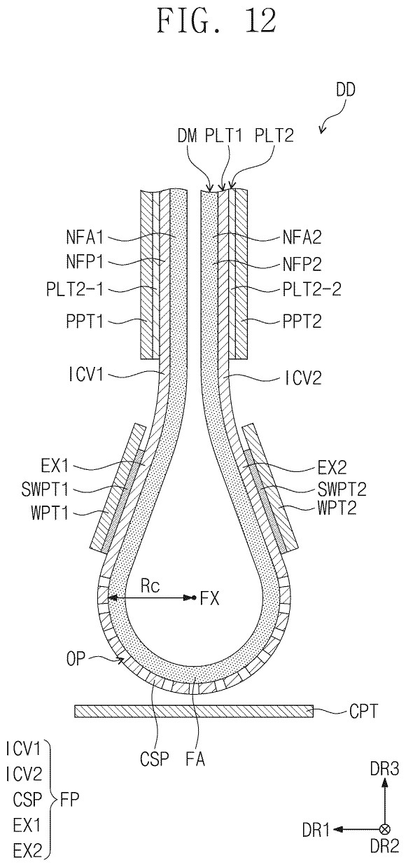

The first non-folding part NFP1 may be disposed below the first non-folding area NFA1 to overlap with the first non-folding area NFA1. The second non-folding part NFP2 may be disposed below the second non-folding area NFA2 to overlap with the second non-folding area NFA2. The folding part FP may be disposed below the folding area FA to overlap with the folding area FA. When the display device DD is folded, the folding part FP may be folded. The folded state of the folding part FP will be described in more detail below with reference to FIG. 12.

The folding part FP may include a curved portion CSP, a first extension portion EX1, a second extension portion EX2, a first inverse curvature portion ICV1, and a second inverse curvature portion ICV2. For example, boundaries of the curved portion CSP, the first extension portion EX1, the second extension portion EX2, the first inverse curvature portion ICV1, and the second inverse curvature portion ICV2 are shown as dotted lines on the first support plates PLT1 in FIG. 6, and the reference numerals thereof are shown at an upper portion of the display module DM with the dotted lines of the boundaries extending upward.

The curved portion CSP, the first extension portion EX1, the second extension portion EX2, the first inverse curvature portion ICV1, and the second inverse curvature portion ICV2 may be arranged along the first direction DR1. For example, the curved portion CSP may be disposed at a central portion of the folding part FP.

The curved portion CSP may be disposed between the first extension portion EX1 and the second extension portion EX2. The openings OP may be defined in the curved portion CSP. The openings OP may be defined to pass through (e.g., penetrate) portions of the curved portion CSP in the third direction DR3. As the openings OP are defined in the curved portion CSP, a flexibility of the curved portion CSP may be improved. In this case, when the folding part FP is folded, the curved portion CSP may be more easily folded. The folded state of the curved portion CSP will be described in more detail below with reference to FIG. 12.

The sixth adhesive layer AL6 may not overlap with the curved portion CSP. In other words, the sixth adhesive layer AL6 may be opened in an area overlapping with the curved portion CSP.

The first extension portion EX1 may be disposed between the curved portion CSP and the first non-folding part NFP1. The second extension portion EX2 may be disposed between the curved portion CSP and the second non-folding part NFP2. In more detail, the first extension portion EX1 may be disposed between the first inverse curvature portion ICV1 and the curved portion CSP, and the second extension portion EX2 may be disposed between the second inverse curvature portion ICV2 and the curved portion CSP.

The first inverse curvature portion ICV1 may be disposed between the first extension portion EX1 and the first non-folding part NFP1. The second inverse curvature portion ICV2 may be disposed between the second extension portion EX2 and the second non-folding part NFP2.

The cover layer COV may be disposed below the first support plate PLT1. The cover layer COV may overlap with the first non-folding part NFP1, the curved portion CSP, and the second non-folding part NFP2. The cover layer COV may cover the openings OP defined in the curved portion CSP from below (e.g., from underneath) the curved portion CSP.

The cover layer COV may not overlap with the first extension portion EX1, the first inverse curvature portion ICV1, the second extension portion EX2, and the second inverse curvature portion ICV2. In other words, the cover layer COV may be opened in areas overlapping with the first extension portion EX1, the first inverse curvature portion ICV1, the second extension portion EX2, and the second inverse curvature portion ICV2.

The cover layer COV may have an elastic modulus that is less than that of the first support plate PLT1. For example, the cover layer COV may include a thermoplastic polyurethane or a rubber, but the material of the cover layer COV is not limited thereto. The cover layer COV may be manufactured in the form of a sheet, and may be attached to the first support plate PLT1.

The second support plate PLT2 may be disposed below the first support plate PLT1. The second support plate PLT2 may overlap with the first non-folding part NFP1 and the second non-folding part NFP2, and may not overlap with the folding part FP. The second support plate PLT2 may be disposed below (e.g., underneath) the cover layer COV overlapping with the first and second non-folding parts NFP1 and NFP2.

The second support plate PLT2 may have a rigidity greater than that of the display module DM. The second support plate PLT2 may include a metal, such as copper and/or a nickel alloy, but the present disclosure is not limited thereto, and the second support plate PLT2 may include various suitable metal materials. The second support plate PLT2 may have a heat dissipation function.

The second support plate PLT2 may include a second-1 support plate PLT2-1 and a second-2 support plate PLT2-2, which are arranged along the first direction DR1. The second-1 support plate PLT2-1 may be disposed below (e.g., underneath) the first non-folding part NFP1 to overlap with the first non-folding part NFP1. The second-2 support plate PLT2-2 may be disposed below the second non-folding part NFP2 to overlap with the second non-folding part NFP2.

The second-1 and second-2 support plates PLT2-1 and PLT2-2 may supplement a support function of the first support plate PLT1 for supporting the display module DM. For example, the second-1 support plate PLT2-1 may support the first non-folding area NFA1, and the second-2 support plate PLT2-2 may support the second non-folding area NFA2.

Portions of the cover layer COV overlapping with the first and second non-folding parts NFP1 and NFP2 may be disposed between the first support plate PLT1 and the second-1 support plate PLT2-1, and between the first support plate PLT1 and the second-2 support plate PLT2-2.

The flat plates PPT1 and PPT2 may be disposed below (e.g., underneath) the first and second non-folding parts NFP1 and NFP2, respectively. The flat plates PPT1 and PPT2 may include a first flat plate PPT1 and a second flat plate PPT2, which are arranged along the first direction DR1. The first flat plate PPT1 may be disposed below the first non-folding part NFP1. The second flat plate PPT2 may be disposed below the second non-folding part NFP2. Each of the first and second flat plates PPT1 and PPT2 may include a metal material.

In more detail, the first flat plate PPT1 may be disposed below the second-1 support plate PLT2-1 to overlap with the second-1 support plate PLT2-1. The second flat plate PPT2 may be disposed below the second-2 support plate PLT2-2 to overlap with the second-2 support plate PLT2-2.

According to the above-described structure, the second-1 support plate PLT2-1 may be disposed between the first non-folding part NFP1 and the first flat plate PPT1, and the second-2 support plate PLT2-2 may be disposed between the second non-folding part NFP2 and the second flat plate PPT2.

The wing plates WPT1 and WPT2 may be disposed below (e.g., underneath) the folding part FP, and may be spaced apart from each other in the first direction DR1. The wing plates WPT1 and WPT2 may include a first wing plate WPT1 and a second wing plate WPT2, which are arranged along the first direction DR1. Each of the first and second wing plates WPT1 and WPT2 may include a metal material.

The first wing plate WPT1 may be disposed below the folding part FP, and may be adjacent to the first flat plate PPT1 in the first direction DR1. The second wing plate WPT2 may be disposed below the folding part FP, and may be adjacent to the second flat plate PPT2 in the first direction DR1. The first and second wing plates WPT1 and WPT2 may be disposed between the first flat plate PPT1 and the second flat plate PPT2.

When the folding part FP is unfolded, the first wing plate WPT1 may be disposed below the first extension portion EX1 to overlap with the first extension portion EX1. When the folding part FP is unfolded, the second wing plate WPT2 may be disposed below the second extension portion EX2 to overlap with the second extension portion EX2. When the folding part FP is unfolded, the first and second wing plates WPT1 and WPT2 may not overlap with the curved portion CSP.

The center plate CPT may be disposed below (e.g., underneath) the folding part FP to overlap with the curved portion CSP. The center plate CPT may be disposed between the first wing plate WPT1 and the second wing plate WPT2. In some embodiments, the center plate CPT may be connected to a hinge for folding the display device. The center plate CPT may include a metal material.

The sub-wing plates SWPT1 and SWPT2 may be disposed below (e.g., underneath) the folding part FP, and may be spaced apart from each other in the first direction DR1. The sub-wing plates SWPT1 and SWPT2 may include a first sub-wing plate SWPT1 and a second sub-wing plate SWPT2, which are arranged along the first direction DR1. Each of the first and second sub-wing plates SWPT1 and SWPT2 may include a metal material, such as stainless steel, but the present disclosure is not limited thereto, and each of the first and second sub-wing plates SWPT1 and SWPT2 may include various suitable metal materials.

The first sub-wing plate SWPT1 may be disposed below the folding part FP, and may be adjacent to the second-1 support plate PLT2-1. The second sub-wing plate SWPT2 may be disposed below the folding part FP, and may be adjacent to the second-2 support plate PLT2-2. The first and second sub-wing plates SWPT1 and SWPT2 may be disposed between the second-1 support plate PLT2-1 and the second-2 support plate PLT2-2.

The first sub-wing plate SWPT1 may be disposed between the folding part FP and the first wing plate WPT1, and the second sub-wing plate SWPT2 may be disposed between the folding part FP and the second wing plate WPT2. In more detail, the first sub-wing plate SWPT1 may be disposed between the first extension portion EX1 and the first wing plate WPT1, and the second sub-wing plate SWPT2 may be disposed between the second extension portion EX2 and the second wing plates WPT2.

When the folding part FP is unfolded, the first sub-wing plate SWPT1 may be disposed below (e.g., underneath) the first extension portion EX1 to overlap with the first extension portion EX1. When the folding part FP is unfolded, the second sub-wing plate SWPT2 may be disposed below (e.g., underneath) the second extension portion EX2 to overlap with the second extension portion EX2. When the folding part FP is unfolded, the first and second sub-wing plates SWPT1 and SWPT2 may not overlap with the curved portion CSP.

The seventh adhesive layer AL7 may be disposed between a portion of the cover layer COV, which overlaps with the first non-folding part NFP1, and the second-1 support plate PLT2-1. In addition, the seventh adhesive layer AL7 may be disposed between a portion of the cover layer COV, which overlaps with the second non-folding part NFP2, and the second-2 support plate PLT2-2. The first and second non-folding parts NFP1 and NFP2 and the second-1 and second-2 support plates PLT2-1 and PLT2-2 may be bonded to each other by the seventh adhesive layer AL7.

The first-1 adhesive layer ADH1-1 may be disposed between the folding part FP and the first sub-wing plate SWPT1, and the first-2 adhesive layer ADH1-2 may be disposed between the folding part FP and the second sub-wing plate SWPT2. In more detail, the first-1 adhesive layer ADH1-1 may be disposed between the first extension portion EX1 and the first sub-wing plate SWPT1, and the first-2 adhesive layer ADH1-2 may be disposed between the second extension portion EX2 and the second sub-wing plate SWPT2. The first and second sub-wing plates SWPT1 and SWPT2 and the first and second extension portions EX1 and EX2 may be bonded to each other by the first-1 and first-2 adhesive layers ADH1-1 and ADH1-2.

The second-1 adhesive layer ADH2-1 may be disposed between the first wing plate WPT1 and the first sub-wing plate SWPT1. The second-2 adhesive layer ADH2-2 may be disposed between the second wing plate WPT2 and the second sub-wing plate SWPT2. The first and second wing plates WPT1 and WPT2 and the first and second sub-wing plates SWPT1 and SWPT2 may be bonded to each other by the second-1 and second-2 adhesive layers ADH2-1 and ADH2-2.

The third-1 adhesive layer ADH3-1 may be disposed between the second-1 support plate PLT2-1 and the first flat plate PPT1. The third-2 adhesive layer ADH3-2 may be disposed between the second-2 support plate PLT2-2 and the second flat plate PPT2. The second-1 and second-2 support plates PLT2-1 and PLT2-2 and the first and second flat plates PPT1 and PPT2 may be bonded to each other by the third-1 and third-2 adhesive layers ADH3-1 and ADH3-2.

Each of the seventh adhesive layer AL7, the first-1 and first-2 adhesive layers ADH1-1 and ADH1-2, the second-1 and second-2 adhesive layers ADH2-1 and ADH2-2, and the third-1 and third-2 adhesive layers ADH3-1 and ADH3-2 may include a transparent adhesive, such as a pressure sensitive adhesive (PSA) or an optically clear adhesive (OCA), but the kinds of the adhesives are not limited thereto.

A thickness of the first support plate PLT1 may be greater than that of the second support plate PLT2, and a thickness of the second support plate PLT2 may be greater than that of the window protective layer WP. For example, the first support plate PLT1 may have a thickness of about 100 micrometers (μm), and the second support plate PLT2 may have a thickness of about 86 micrometers (μm).

A thickness of the cover layer COV may be the same or substantially the same as the thickness of the sixth adhesive layer AL6, and a thickness of the seventh adhesive layer AL7 may be the same or substantially the same as the thickness of the third adhesive layer AL3. For example, the cover layer COV may have a thickness of about 16 micrometers (μm), and the seventh adhesive layer AL7 may have a thickness of about 50 micrometers (μm).

The first-1 adhesive layer ADH1-1 and the first sub-wing plate SWPT1 may have the same or substantially the same thickness as each other. The first-second adhesive layer ADH1-2 and the second sub-wing plate SWPT2 may have the same or substantially the same thickness as each other. The first-1 adhesive layer ADH1-1, the first-2 adhesive layer ADH1-2, the first sub-wing plate SWPT1, and the second sub-wing plate SWPT2 may have the same or substantially the same thickness as each other. For example, the thickness of each of the first-1 adhesive layer ADH1-1, the first-2 adhesive layer ADH1-2, the first sub-wing plate SWPT1, and the second sub-wing plate SWPT2 may be about 50 microns (μm).

The second-1 adhesive layer ADH2-1 and the second-2 adhesive layer ADH2-2 may have the same or substantially the same thickness as each other. Each of the second-1 and second-2 adhesive layers ADH2-1 and ADH2-2 may have a thickness greater than that of each of the first-1 and first-2 adhesive layers ADH1-1 and ADH1-2. In addition, each of the second-1 and second-2 adhesive layers ADH2-1 and ADH2-2 may have a thickness greater than that of each of the first and second sub-wing plates SWPT1 and SWPT2. For example, the thickness of each of the second-1 and second-2 adhesive layers ADH2-1 and ADH2-2 may be about 100 micrometers (μm).

The third-1 adhesive layer ADH3-1 may have a thickness greater than that of the second-1 adhesive layer ADH2-1. The third-2 adhesive layer ADH3-2 may have a thickness greater than that of the second-2 adhesive layer ADH2-2. Each of the first and second wing plates WPT1 and WPT2 and the first and second flat plates PPT1 and PPT2 may have a thickness greater than that of the first support plate PLT1.

A width of the first support plate PLT1 may be larger than that of the display module DM. When viewed on the plane (e.g., in a plan view), an edge of the display module DM may be disposed inside an edge of the first support plate PLT1.

The cover layer COV and the seventh adhesive layer AL7 may have the same or substantially the same width as each other. When viewed on the plane, the edges of the cover layer COV and the seventh adhesive layer AL7 may be disposed inside the edge of the first support plate PLT1.

When viewed on the plane, the edge of the second support plate PLT2 may be disposed between the edge of the first support plate PLT1 and the edge of the cover layer COV.

Each of the third-1 and third-2 adhesive layers ADH3-1 and ADH3-2 may have a width less than those of each of the second-1 and second-2 support plates PLT2-1 and PLT2-2 and each of the first and second flat plates PLT1 and PLT2.

One side of the third-1 adhesive layer ADH3-1, which is adjacent to the first wing plate WPT1, may be spaced apart from one side of the second-1 support plate PLT2-1, which is adjacent to the first sub-wing plate SWPT1. One side of the third-2 adhesive layer ADH3-2, which is adjacent to the second wing plate WPT2, may be spaced apart from one side of the second-2 support plate PLT2-2, which is adjacent to the second sub-wing plate SWPT2.

In the first direction DR1, the first wing plate WPT1 may have a width greater than that of the first sub-wing plate SWPT1. In the first direction DR1, the second wing plate WPT2 may have a width greater than that of the second sub-wing plate SWPT2. Thus, each of the first and second wing plates WPT1 and WPT2 may have a width greater than that of each of the first and second sub-wing plates SWPT1 and SWPT2.

In the first direction DR1, the first-1 adhesive layer ADH1-1 may have a width less than that of the first sub-wing plate SWPT1. Both sides (e.g., opposite sides) of the first-1 adhesive layer ADH1-1, which are opposite to each other in the first direction DR1, may be disposed inside both sides (e.g., opposite sides) of the first sub-wing plate SWPT1, which are opposite to each other in the first direction DR1.

In the first direction DR1, the first-2 adhesive layer ADH1-2 may have a width less than that of the second sub-wing plate SWPT2. Both sides (e.g., opposite sides) of the first-2 adhesive layer ADH1-2, which are opposite to each other in the first direction DR1, may be disposed inside both sides (e.g., opposite sides) of the second sub-wing plate SWPT2, which are opposite to each other in the first direction DR1.

In the first direction DR1, the second-1 adhesive layer ADH2-1 may have a width less than that of the first-1 adhesive layer ADH1-1. The second-1 adhesive layer ADH2-1 may be adjacent to one side of the first sub-wing plate SWPT1, which faces the second sub-wing plate SWPT2. One side of the second-1 adhesive layer ADH2-1 may overlap with one side of the first sub-wing plate SWPT1, which faces the second sub-wing plate SWPT2.

The second-1 adhesive layer ADH2-1 may be adjacent to one side of the first wing plate WPT1, which faces the second wing plate WPT2. In other words, the second-1 adhesive layer ADH2-1 may be adjacent to one side of the first wing plate WPT1, which does not face the first flat plate PPT1.

In the first direction DR1, the second-2 adhesive layer ADH2-2 may have a width less than that of the first-2 adhesive layer ADH1-2. The second-2 adhesive layer ADH2-2 may be adjacent to one side of the second sub-wing plate SWPT2, which faces the first sub-wing plate SWPT1. One side of the second-2 adhesive layer ADH2-2 may overlap with one side of the second sub-wing plate SWPT2, which faces the first sub-wing plate SWPT1.

The second-2 adhesive layer ADH2-2 may be adjacent to one side of the second wing plate WPT2, which faces the first wing plate WPT1. In other words, the second-2 adhesive layer ADH2-2 may be adjacent to one side of the second wing plate WPT2, which does not face the second flat plate PPT2.

In the first direction DR1, a first width WT1 of an opening of the sixth adhesive layer AL6 may be about 12.95 mm. In the first direction DR1, a second width WT2 of an area in which the openings OP are defined may be about 11.12 mm. In the first direction DR1, a third width WT3 of the cover layer COV covering the openings OP may be about 12.15 mm.

In the first direction DR1, a first distance DT1 between the first wing plate WPT1 and the second wing plate WPT2 may be about 13.14 mm. In the first direction DR1, a second distance DT2 between the first flat plate PPT1 and the second flat plate PPT2 may be about 26.6 mm.

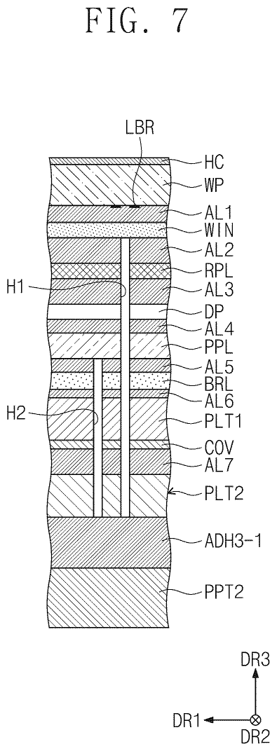

FIG. 7 is a cross-sectional view taken along the line II-II′ of FIG. 3.

Referring to FIG. 7, a first hole H1 and a second hole H2 may be defined in the support part SUP and the display module DM. When viewed on the plane, a light blocking pattern LBP may be disposed around the first hole H1 and the second hole H2. The light blocking pattern LBP may be disposed at (e.g., in or on) the same layer as that of the printing layer PIT. In other words, the light blocking pattern LBP may be disposed on the bottom surface of the window protective layer WP.

The first hole H1 may be defined from the second support plate PLT2 to the second adhesive layer AL2. For example, the first hole H1 may be defined in (e.g., may penetrate) the second support plate PLT2, the cover layer COV, the first support plate PLT1, the barrier layer BRL, the panel protective layer PPL, the display panel DP, the anti-reflection layer RPL, and the second to seventh adhesive layers AL2 to AL7.

The second hole H2 may be defined from the second support plate PLT2 to the fifth adhesive layer AL5. For example, the second hole H2 may be defined in (e.g., may penetrate) the second support plate PLT2, the cover layer COV, the first support plate PLT1, the barrier layer BRL, and the fifth to seventh adhesive layers AL5 to AL7).

The above-described camera CM may be disposed in the first hole H1. The above-described sensor SN may be disposed in the second hole H2. Optical signals may be provided to the camera CM and the sensor SN through the first and second holes H1 and H2.

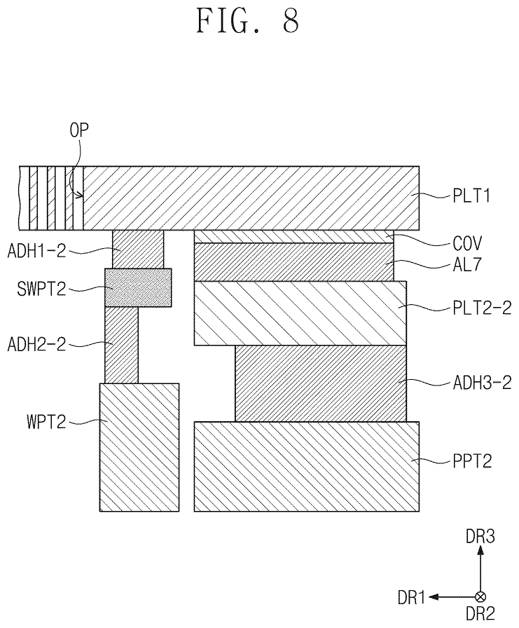

FIG. 8 is an enlarged view illustrating the second non-folding part and the elements below the second non-folding part in FIG. 6.

Referring to FIGS. 6 and 8, the second sub-wing plate SWPT2 may be disposed between the first-2 adhesive layer ADH1-2 and the second-2 adhesive layer ADH2-2. When the second sub-wing plate SWPT2 is not used, a single adhesive layer may be used between the first support plate PLT1 and the second wing plate WPT2.

The single adhesive layer may have the same or substantially the same thickness as that of a sum of the thicknesses of the first-2 adhesive layer ADH1-2, the second-2 adhesive layer ADH2-2, and the second sub-wing plate SWPT2. For example, the thickness of the single adhesive layer may be about 200 micrometers (μm). When the thicker single adhesive layer is disposed between the first support plate PLT1 and the second wing plate WPT2, a shape of the single adhesive layer may be visible to the user from the outside. As a result, a display quality may be deteriorated.

In an embodiment of the present disclosure, the second sub-wing plate SWPT2 may be disposed between the first support plate PLT1 and the second wing plate WPT2, and thus, the single adhesive layer may not be used. The first-2 adhesive layer ADH1-2 and the second-2 adhesive layer ADH2-2, each of which has a thickness less than that of the single adhesive layer, may be disposed above and below the second sub-wing plate WPT2. The first-2 adhesive layer ADH1-2 and the second-2 adhesive layer ADH2-2, each of which has a thickness less than that of the single adhesive layer, may not be visible from the outside. Thus, the image quality may be improved.

Similarly, regarding the first sub-wing plate SWPT1, the first-1 adhesive layer ADH1-1 and the second-1 adhesive layer ADH2-1, each of which has a thickness less than that of the single adhesive layer, may be disposed above and below (e.g., underneath) the first sub-wing plate SWPT1. Thus, the first-1 adhesive layer ADH1-1 and the second-1 adhesive layer ADH2-1 may not be visible from the outside.

The second wing plate WPT2 may cover the second extension portion EX2 from below the second extension portion EX2, and may support the second extension portion EX2. The second sub-wing plate SWPT2 may be used to dispose the adhesive layers ADH1-2 and ADH2-2, each of which has a thickness less than that of the single adhesive layer, and the second wing plate WPT2 may cover the second extension portion EX2. Thus, the second sub-wing plate SWPT2 may not have a large width, and may have a width less than that of the second wing plate WPT2.

The first wing plate WPT1 may cover the first extension portion EX1 from below the first extension portion EX1, and may support the first extension portion EX1. The first sub-wing plate SWPT1 may be used to dispose the adhesive layers ADH1-1 and ADH2-1, each of which has a thickness less than that of the single adhesive layer, and the first wing plate WPT1 may cover the first extension portion EX1. Thus, the first sub-wing plate SWPT1 may not have a large width, and may have a width less than that of the first wing plate WPT1.

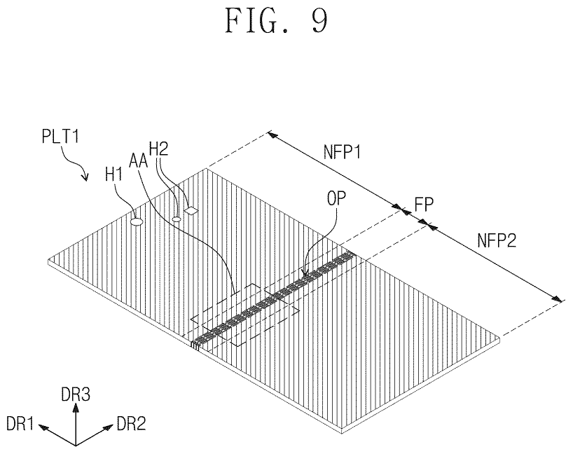

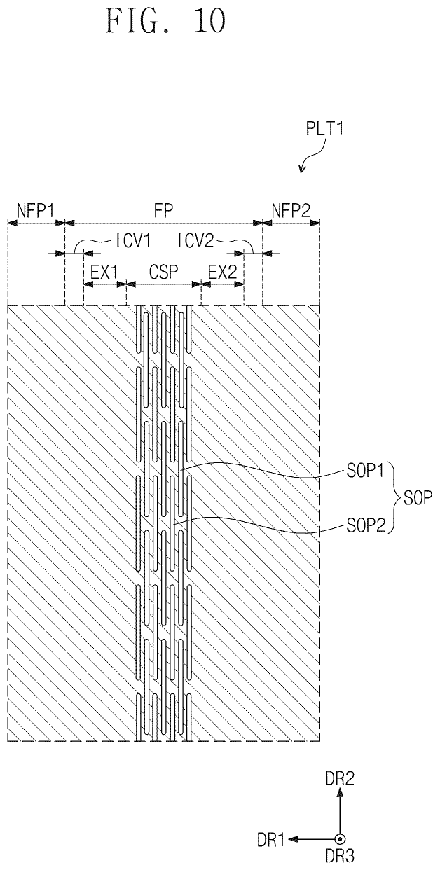

FIG. 9 is a perspective view of a support plate of FIG. 6. FIG. 10 is an enlarged plan view illustrating the area AA of FIG. 9.

Referring to FIGS. 9 and 10, the first support plate PLT1 may include a first non-folding part NFP1, a folding part FP, and a second non-folding part NFP2, which are arranged along the first direction DR1. The folding part FP may include a first inverse curvature portion ICV1, a first extension portion EX1, a curved portion CSP, a second extension portion EX2, and a second inverse curvature portion ICV2, which are arranged along the first direction DR1.

A grid pattern may be defined on the curved surface portion CSP. For example, the openings OP defined in the curved portion CSP may be arranged according to a suitable rule (e.g., a predetermined rule). The openings OP may be arranged in a grid shape to provide the grid pattern of the curved portion CSP.

A first hole H1 and a second holes H2 may be defined in the first non-folding part NFP1. The first hole H1 and the second holes H2 may be adjacent to an edge of the first non-folding part NFP1. The first hole H1 may correspond to the first hole H1 described above with reference to FIG. 7, and the camera CM described above may be disposed in the first hole H1. The second holes H2 may correspond to the second hole H2 described above with reference to FIG. 7, and one or more of the sensors SN described above may be disposed in the second hole H2.

The openings OP may extend to be longer in the second direction DR2 than in the first direction DR1. The openings OP may include a plurality of first sub-openings SOP1 arranged along the second direction DR2, and a plurality of second sub-openings SOP2 arranged along the second direction DR2 so as to be adjacent to the first sub-openings SOP1 in the first direction DR1. The first sub-openings SOP1 may be disposed alternately with the second sub-openings SOP2.

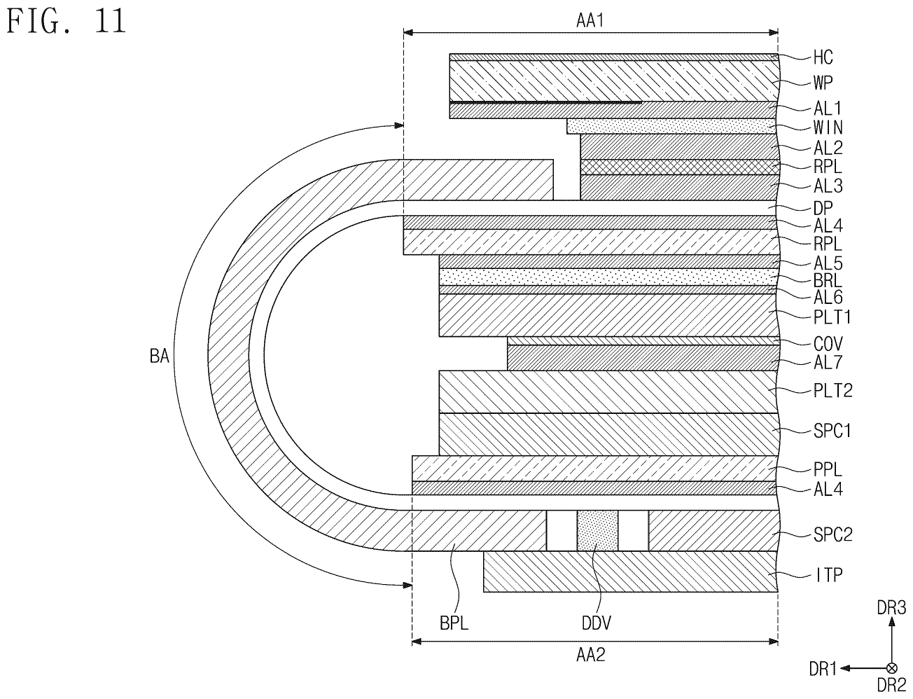

FIG. 11 is a cross-sectional view taken along the line III-III′ of FIG. 3 in a state in which a bending area is bent.

Referring to FIG. 11, the data driver DDV may be disposed on the second area AA2. As used herein, the phrase “disposed on the second area AA2” may refer to a lower side of the second area AA2 based on the bending state of FIG. 11.

The data driver DDV may be defined as a driving IC. The bending area BA may be bent, so that the second area AA2 is disposed under the first area AA1. Therefore, the data driver DDV may be disposed below (e.g., underneath) the first area AA1. The bending area BA may be bent to be convex toward the outside of the display panel DP. The bending area BA may be bent to have a desired curvature (e.g., a predetermined curvature).

The display device DD may include a protective layer BPL. The protective layer BPL may be disposed on the bending area BA, a portion of the first area AA1 adjacent to the bending area BA, and a portion of the second area AA2 adjacent to the bending area BA. The protective layer BPL may continuously extend from a portion of the first area AA1 adjacent to the bending area BA, across the bending area BA, and to a portion of the second area AA2 adjacent to the bending area BA.

The protective layer BPL may be spaced apart from the anti-reflection layer RPL, and may be disposed below (e.g., underneath) the window protective layer WP on the first area AA1. The protective layer BPL may be spaced apart from the data driver DDV on the second area AA2. The protective layer BPL may include an acrylic resin or a urethane resin. The protective layer BPL may be bent together with the bending area BA.

The protective layer BPL may serve to protect the bending area BA. The protective layer BPL may cover lines disposed on the bending area BA to protect the lines disposed on the bending area BA. The protective layer BPL may complement a rigidity of the bending area BA, and when the bending area BA is bent, the bending area BA may be prevented or substantially prevented from being cracked. The protective layer BPL may protect the bending area BA against external impacts. The protective layer BPL may have a thickness of about 80 micrometers (μm) in the third direction DR3.

The panel protective layer PPL may not be disposed on an area overlapping with the bending area BA. Because the panel protective layer PPL is not disposed on the bending area BA, the bending area BA may be more easily bent. If the panel protective layer PPL is also disposed below the bending area BA, a thickness of the area on which the bending area BA is disposed may be thicker, and thus, the bending of the bending area BA may be more difficult.

Sides of the window protective layer WP and the first adhesive layer AL1, which face the bending area BA, may overlap with each other. Sides of the window protective layer WP and the first adhesive layer AL1 may be disposed outside one side of the window WIN, which faces the bending area BA.

Sides of the anti-reflection layer RPL and the second and third adhesive layers AL2 and AL3, which face the bending area BA, may overlap with each other. Sides of the anti-reflection layer RPL and the second and third adhesive layers AL2 and AL3 may be disposed inside one side of the window WIN.

Sides of the barrier layer BRL, the fifth and sixth adhesive layers AL5 and AL6, and the first support plate PLT1, which face the bending area BA, may overlap with each other. Sides of the barrier layer BRL, the fifth and sixth adhesive layers AL5 and AL6, and the first support plate PLT1 may be disposed outside one side of the window protective layer WP.

Sides of the cover layer COV and the seventh adhesive layer AL7, which face the bending area BA, may overlap with each other. Sides of the cover layer COV and the seventh adhesive layer AL7 may be disposed inside one side of the window protective layer WP and outside one side of the window WIN.

A first spacer SPC1 may be disposed between the panel protective layer PPL and the second support plate PLT2 on the second area AA2. A thickness of the first spacer SPC1 may be about 100 micrometers (μm). One side of the first spacer SPC1 and one side of the second support plate PLT2, which face the bending area BA, may overlap with each other. The sides of the first spacer SPC1 and the second support plate PLT2 may overlap with one side of the first support plate PLT1.

Sides of the panel protective layer PPL and the fourth adhesive layer AL4, which are adjacent to the bending area BA, may be disposed outside the first support plate PLT1.

The second spacer SPC2 may be disposed on the second area AA2 adjacent to the data driver DDV. The data driver DDV may be disposed between the protective layer BPL and the second spacer SPC2 in the second area AA2.

Each of the first and second spacers SPC1 and SPC2 may be a double-sided tape. For example, each of the first and second spacers SPC1 and SPC2 may include a flexible base layer, such as polyethylene terephthalate, and an adhesive disposed on top and bottom surfaces of the base layer.

A cover tape ITP may be disposed on the second area AA2 to cover the data driver DDV, a portion of the protective layer BPL, which is adjacent to the data driver DDV, and the second spacer SPC2. The cover tape ITP may include an insulating tape.

FIG. 12 is a view illustrating a folded state of the display device of FIG. 6.

For convenience of illustration, in FIG. 12, the display module DM is illustrated as a single layer. In addition, for convenience of illustration, the first support plate PLT1, the second support plate PLT2, the first and second wing plates WPT1 and WPT2, the first and second flat plates PPT1 and PPT2, the first and second sub-wing plates SWPT1 and SWPT2, and the center plate CPT are illustrated together with the display module DM, and the other components are not shown.

Referring to FIG. 12, the first support plate PLT1 may be folded around the folding axis FX. The first support plate PLT1 may be folded into a dumbbell shape. The first support plate PLT1 may be folded, so that the display module DM is folded together with the first support plate PLT1.

The folding part FP may be folded around the folding axis FX to fold the first support plate PLT1. When the folding part FP is folded, the curved portion CSP may be bent at a desired curvature (e.g., a predetermined curvature). The curved portion CSP may be curved to have a desired radius of curvature (e.g., a predetermined radius of curvature) Rc. As the folding part FP is folded, the folding area FA may be folded.

The first inverse curvature portion ICV1 may be bent in a direction opposite to that of the curved portion CSP. The second inverse curvature portion ICV2 may be bent in a direction opposite to that of the curved portion CSP. The second inverse curvature ICV2 may have a shape symmetrical or substantially symmetrical to that of the first inverse curvature ICV1.

When the folding part FP is folded, the first and second non-folding parts NFP1 and NFP2 and the second-1 and second-2 support plates PLT2-1 and PLT2-2 may be maintained or substantially maintained in a flat state. Thus, the first and second non-folding areas NFA1 and NFA2 may be maintained or substantially maintained in the flat state by the first and second non-folding parts NFP1 and NFP2 and the second-1 and second-2 support plates PLT2-1 and PLT2-2.

When the folding part FP is folded, a distance between the first non-folding part NFP1 and the second non-folding part NFP2 in the first direction DR1 may be less than a diameter of a circle having the radius of curvature Rc. According to this structure, the first support plate PLT1 may be folded into a dumbbell shape.

The first extension portion EX1 may be maintained or substantially maintained in the flat state between the curved surface CSP and the first inverse curvature portion ICV1. The first extension portion EX1 may be maintained or substantially maintained in the flat state by the first wing plate WPT1 and the first sub-wing plate SWPT1, which are maintained or substantially maintained in the flat state.

The center plate CPT may be disposed below (e.g., underneath) the curved portion CSP to cover the curved portion CSP.

The second extension portion EX2 may be maintained or substantially maintained in the flat state between the curved portion CSP and the second inverse curvature ICV2. The second extension portion EX2 may be maintained or substantially maintained in the flat state by the second wing plate WPT2 and the second sub-wing plate SWPT2, which are maintained or substantially maintained in the flat state.

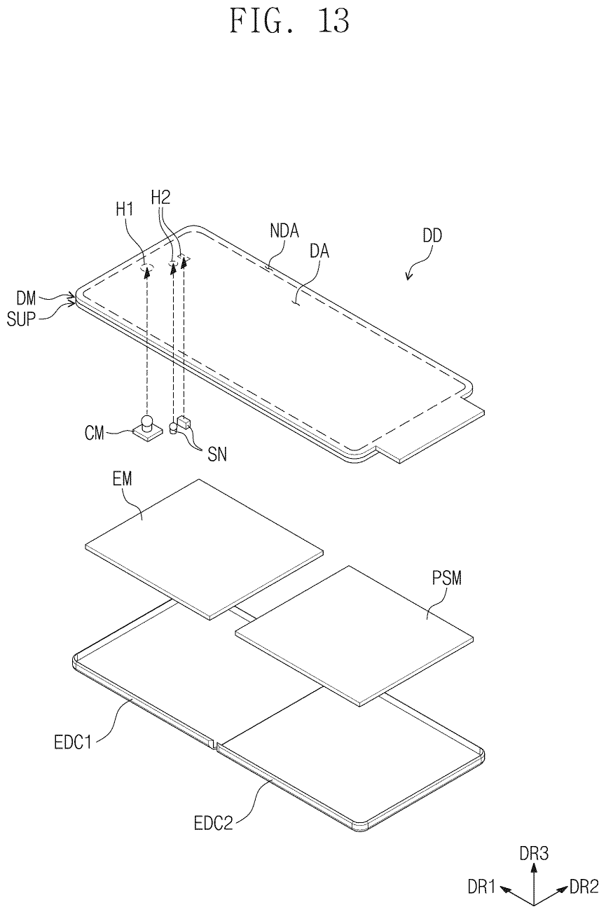

FIG. 13 is a view of a case in which a display module and a support part are accommodated therein according to an embodiment of the present disclosure.

Referring to FIG. 13, the display device ED may further include an electronic module EM, a power module PSM, and cases EDC1 and EDC2, in addition to the display module DM, the support part SUP, the camera CM, and the sensors SN. Although not separately shown, the display device DD may further include a hinge structure for controlling a folding operation of the display device DD.

As described above, the first and second holes H1 and H2 may be defined in the display device DD, the camera CM may be disposed in the first hole H1, and the sensors SN may be disposed in the second holes H2.

The electronic module EM and the power module PSM may be disposed below the support part SUP. Although not shown, the electronic module EM and the power module PSM may be connected to each other through a flexible printed circuit board. The electronic module EM may control an operation of the display module DM. The power module PSM may supply power to the display module DM.

The cases EDC1 and EDC2 may accommodate the display module DM, the support part SUP, the camera CM, the sensors SN, the electronic module EM, and the power module PSM. The cases EDC1 and EDC2 may be divided into two first and second cases EDC1 and EDC2 to fold the display device DD. The cases EDC1 and EDC2 may protect the display module DM, the support part SUP, the camera CM, the sensors SN, the electronic module EM, and the power module PSM.

According to some embodiments of the present disclosure, the sub-wing plate may be disposed between the wing plates and the folding part of the first support plate to reduce a thickness of the adhesive layers, through which the wing plates are adhered to the folding part of the first support plate. Because the thickness of the adhesive layers may be reduced, the adhesive layers may not be visible from the outside.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a display module;
a first support plate below the display module, and comprising a first non-folding part and a folding part along a first direction;
a first flat plate below the first non-folding part;
a first wing plate below the folding part, and adjacent to the first flat plate in the first direction; and
a first sub-wing plate between the folding part and the first wing plate,
wherein the first wing plate has a width greater than that of the first sub-wing plate in the first direction.

2. The display device of claim 1, further comprising a first-1 adhesive layer between the folding part and the first sub-wing plate.

3. The display device of claim 2, wherein the first-1 adhesive layer and the first sub-wing plate have the same thickness as each other in a direction perpendicular to a plane of the display module.

4. The display device of claim 2, wherein the first-1 adhesive layer has a width less than that of the first sub-wing plate in the first direction.

5. The display device of claim 2, further comprising a second-1 adhesive layer between the first wing plate and the first sub-wing plate.

6. The display device of claim 5, wherein the second-1 adhesive layer has a thickness greater than that of the first-1 adhesive layer in a direction perpendicular to a plane of the display module.

7. The display device of claim 5, wherein the second-1 adhesive layer has a width less than that of the first-1 adhesive layer in the first direction, and is located adjacent to one side of the first wing plate that does not face the first flat plate.

8. The display device of claim 5, wherein the second-1 adhesive layer has a thickness greater than that of the first sub-wing plate in a direction perpendicular to a plane of the display module.

9. The display device of claim 5, further comprising:
a second-1 support plate between the first non-folding part and the first flat plate; and
a third-1 adhesive layer between the second-1 support plate and the first flat plate.

10. The display device of claim 9, wherein the third-1 adhesive layer has a thickness greater than that of the second-1 adhesive layer in a direction perpendicular to a plane of the display module.

11. The display device of claim 1, wherein the first support plate further comprises a second non-folding part along the first direction together with the first non-folding part and the folding part,
wherein the folding part is located between the first non-folding part and the second non-folding part,
wherein the folding part comprises:
a curved portion having a plurality of openings defined therein;
a first extension portion between the curved portion and the first non-folding part;
a second extension portion between the curved portion and the second non-folding part;
a first inverse curvature portion between the first extension portion and the first non-folding part; and
a second inverse curvature portion between the second extension portion and the second non-folding part,
wherein, when the folding part is folded, the curved portion is bent to have a curvature, and
wherein the first and second inverse curvature portions are configured to be bent in a direction opposite to that of the curved portion.

12. The display device of claim 11, further comprising:
a second flat plate below the second non-folding part;
a second wing plate below the folding part, adjacent to the second flat plate in the first direction, and located together with the first wing plate along the first direction; and
a second sub-wing plate between the folding part and the second wing plate,
wherein the second wing plate has a width greater than that of the second sub-wing plate in the first direction.

13. The display device of claim 12, wherein, when the folding part is unfolded, the first wing plate and the first sub-wing plate overlap with the first extension portion, and the second wing plate and the second sub-wing plate overlap with the second extension portion, and
wherein the first and second wing plates and the first and second sub wing-plates do not overlap with the curved portion.

14. The display device of claim 12, further comprising:
a first-2 adhesive layer between the folding part and the second sub-wing plate;
a second-2 adhesive layer between the second wing plate and the second sub-wing plate;
a second-2 support plate between the second non-folding part and the second flat plate; and
a third-2 adhesive layer between the second-2 support plate and the second flat plate.

15. The display device of claim 14, wherein, in a direction perpendicular to a plane of the display module, the first-2 adhesive layer and the second sub-wing plate have the same thickness as each other, and the second-2 adhesive layer has a thickness greater than that of the first-2 adhesive layer, and
wherein the first-2 adhesive layer has a width less than that of the second sub-wing plate in the first direction.

16. The display device of claim 14, wherein the second-2 adhesive layer has a width less than that of the first-2 adhesive layer in the first direction, and
wherein the second-2 adhesive layer is adjacent to one side of the second wing plate that faces the first wing plate.

17. The display device of claim 14, wherein, in a direction perpendicular to a plane of the display module, the second-2 adhesive layer has a thickness greater than that of the second sub-wing plate, and the third-2 adhesive layer has a thickness greater than that of the second-2 adhesive layer.

18. A display device comprising:
a display module;
a first support plate below the display module, and comprising a first non-folding part, a folding part, and a second non-folding part along a first direction;
a first flat plate below the first non-folding part;
a second flat plate below the second non-folding part;
a first wing plate below the folding part, and adjacent to the first flat plate;
a second wing plate below the folding part, and adjacent to the second flat plate;
a first sub-wing plate between the folding part and the first wing plate; and
a second sub-wing plate between the folding part and the second wing plate,
wherein, in the first direction, the first wing plate has a width greater than that of the first sub-wing plate, and the second wing plate has a width greater than that of the second sub-wing plate.

19. The display device of claim 18, further comprising:
a second-1 support plate between the first non-folding part and the first flat plate;
a second-2 support plate between the second non-folding part and the second flat plate;
a first-1 adhesive layer between the folding part and the first sub-wing plate; and
a first-2 adhesive layer between the folding part and the second sub-wing plate,
wherein, in the first direction, the first and second sub-wing plates are located between the second-1 support plate and the second-2 support plate.

20. A display device comprising:
a display module;
a first support plate below the display module, and comprising non-folding parts along a first direction, and a folding part between the non-folding parts;
a first wing plate below the folding part;
a second wing plate below the folding part, and located together with the first wing plate along the first direction;
a first sub-wing plate between the folding part and the first wing plate; and
a second sub-wing plate between the folding part and the second wing plate,
wherein each of the first and second wing plates has a width greater than that of each of the first and second sub-wing plates in the first direction.
